(19) United States
(12) Patent Application Publication
(10) Pub. No.: US 2026/0313809 A1
(43) Pub. Date: Oct. 8, 2026

(54) METHOD FOR MANUFACTURING EMBEDDED TRACE SUBSTRATE

(71) Applicant: NISSHA CO., LTD., Kyoto-shi, Kyoto (JP)

(72) Inventors: Toshifumi KUROSAKI, Otsu-shi, Shiga (JP); Takashi YOKOYAMA, Otsu-shi, Shiga (JP)

(21) Appl. No.: 19/478,730

(22) PCT Filed: Mar. 7, 2024
(86) PCT No.: PCT/JP2024/008746

§ 371 Date: Oct. 24, 2025

(30) Foreign Application Priority Data
Apr. 27, 2023 (JP) 2023-073830

(51) Int. Cl. H05K 3/10; H05B 3/03; H05B 3/48

(52) U.S. Cl. CPC H05K 3/103; H05B 3/03; H05B 3/48; H05B 2203/004; H05B 2203/013; H05B 2203/017; H05K 2203/0495

(57) ABSTRACT

A method is provided that includes preparing a film, arranging two electrode pads at the film along a first direction, forming a circuit including a thin metal wire by embedding the circuit in the film using an ultrasonic welding machine, with the circuit having a functional portion with an arbitrary pattern, two wiring portions led out from both ends of the functional portion, and two end portions extending from the wiring portions in a direction away from the functional portion, partly overlapping the electrode pads, and constituting two positional-deviation absorption regions, and connecting the electrode pads with the thin metal wire located on the electrode pads. The positional-deviation absorption regions are defined by the end portions having a bent shape, and have a width for absorbing positional deviation of the electrode pads in the first direction relative to the circuit.

### CROSS-REFERENCE TO RELATED APPLICATIONS

This application is a U.S. National stage of International Application No. PCT/JP2024/008746 filed on Mar. 7, 2024. This application claims priority to Japanese Patent Application No. 2023-073830 filed on Apr. 27, 2023 with Japan Patent Office.

### BACKGROUND

### Field of the Invention

The present invention relates to a method for manufacturing an embedded trace substrate.

### Background Information

A film heater in which one thin metal wire is embedded in a film in an arbitrary pattern is known (see, for example, JP 2022-066706 A (Patent Literature 1)). Referring to FIGS. 10A and 10B, such a film heater 100 includes a film 200, a first electrode pad 500 and a second electrode pad 600 that have a quadrangular shape and that are arranged along a Y direction at a peripheral edge of the film 200 in parallel to each other with a space therebetween, and a circuit 400 including one thin metal wire 300 embedded in the film 200.

The circuit 400 includes a heater portion 450 having an arbitrary pattern, a first wiring portion 430 and a second wiring portion 440 respectively led out from both ends of the heater portion 450, and a first end portion 410 and a second end portion 420 respectively extending from the first wiring portion 430 and the second wiring portion 440 in a direction (+X direction in FIGS. 10A and 10B) away from the heater portion 450 and overlapping the first electrode pad 500 and the second electrode pad 600, respectively. The circuit 400 is embedded by melting a contact surface of the film 200 with the thin metal wire 300 by applying ultrasonic vibration using an ultrasonic welding machine. For example, the first wiring portion 430, the heater portion 450, the second wiring portion 440, and the second end portion 420 can be embedded in this order from the first end portion 410.

The first end portion 410 and the second end portion 420 respectively straddle the first electrode pad 500 and the second electrode pad 600 in the X direction. Upper surfaces of the first electrode pad 500 and the second electrode pad 600 are electrically connected to the thin metal wire 300 that constitutes the first end portion 410 and the second end portion 420 and that is in contact with the upper surfaces. When a voltage is applied to the first electrode pad 500 and the second electrode pad 600, a current is generated in the circuit 400, and the heater portion 450 generates heat.

### SUMMARY

In a conventional method for manufacturing the film heater 100, first, the electrode pads 500 and 600 are disposed on the film 200, and a corner of the film 200 is set in contact with a jig (not illustrated). Thereafter, the thin metal wire 300 is embedded in the film 200 such that the first end portion 410 and the second end portion 420 overlap the electrode pads 500 and 600. The arrangement of the electrode pads 500 and 600 and the embedding of the thin metal wire 300 are separate processes, resulting in that the following positional deviation occurs. That is, (1) positional deviation of the electrode pads, (2) positional deviation of the embedded position of the thin metal wire, and (3) positional deviation of the electrode pads and the embedded position of the thin metal wire. In this manufacturing method, when the arrangement positions of the electrode pads 500 and 600 are shifted in, for example, the +Y direction in FIG. 10A, the embedded position of the thin metal wire 300 is relatively shifted in the −Y direction in FIG. 10A. That is, in the conventional manufacturing method, it is difficult to align the electrode pads 500 and 600 and the circuit 400, and thus there is a problem that the non-defective rate is hardly increased.

One object of the present disclosure is to provide a method for manufacturing an embedded trace substrate with which it is possible to improve a non-defective rate by increasing the alignment accuracy between a circuit and an electrode pad.

According to a first aspect of the present disclosure for achieving the above-mentioned object, a method for manufacturing an embedded trace substrate includes:
a preparation step of preparing a film;
an arrangement step of arranging a first electrode pad and a second electrode pad at a peripheral edge of a first main surface of the film along a first direction so as to be spaced from each other and parallel to each other;
a circuit formation step of forming a circuit that includes a thin metal wire disposed on the first main surface and that has a functional portion having an arbitrary pattern, a first wiring portion led out from one end of both ends of the functional portion, a second wiring portion led out from another end of both ends of the functional portion, a first end portion constituting a first positional-deviation absorption region, and a second end portion constituting a second positional-deviation absorption region, the first end portion and the second end portion respectively extending from the first wiring portion and the second wiring portion in a direction away from the functional portion and partly overlapping the first electrode pad and the second electrode pad, respectively, the circuit being formed by embedding, in the first main surface of the film, the functional portion, the first wiring portion, the second wiring portion, and sections of the first end portion and the second end portion not overlapping the first electrode pad and the second electrode pad, using an ultrasonic welding machine; and
a connection step of electrically connecting the first electrode pad and the second electrode pad with the thin metal wire located on the first electrode pad and the second electrode pad, wherein
the ultrasonic welding machine includes a horn that melts a contact surface of the film with the thin metal wire by applying ultrasonic vibration and that embeds the thin metal wire into the first main surface of the film, and the thin metal wire to be continuously drawn out from a tip of the horn onto the first main surface of the film through an inside of the horn, and
the first positional-deviation absorption region and the second positional-deviation absorption region are respectively defined by the first end portion and the second end portion having a bent shape, and have a width for absorbing positional deviation of the first electrode pad and the second electrode pad in the first direction relative to the circuit.

According to such a manufacturing method, even when the first electrode pad and the second electrode pad are shifted in the first direction relative to the embedded positions of the first end portion and the second end portion, the first end portion and the second end portion have sections overlapping the first electrode pad and the second electrode pad, respectively, because the first end portion and the second end portion have a bent shape and have a width for absorbing a positional deviation of the first electrode pad and the second electrode pad in the first direction relative to the circuit. That is, the accuracy in alignment between the electrode pads and the circuit is increased, whereby the non-defective rate can be improved.

According to a second aspect of the present disclosure, in the method for manufacturing an embedded trace substrate according to the first aspect, the bent shape has a zigzag shape or a U shape in plan view.

With the method for manufacturing an embedded trace substrate according to the present disclosure, it is possible to improve a non-defective rate by increasing the alignment accuracy between the circuit and the electrode pads.

### BRIEF DESCRIPTION OF THE DRAWINGS

FIGS. 1A, 1B, 1C, 1D, 1E and 1F are schematic perspective views illustrating one embodiment of a method for manufacturing an embedded trace substrate.

FIG. 2 is a partially enlarged view illustrating an example of a first end portion and a second end portion.

FIG. 3 is an enlarged view illustrating a state in which an electrode pad is shifted in a +X direction.

FIG. 4 is a partially enlarged view illustrating another example of the first end portion and the second end portion.

FIG. 5 is an enlarged view illustrating a state in which the electrode pad is shifted in the +X direction.

FIG. 6 is an enlarged view illustrating a state in which the electrode pad is further shifted in the +X direction from the state illustrated in FIG. 5.

FIG. 7 is an enlarged view illustrating a state in which the electrode pad is shifted in a −X direction.

FIG. 8 is an enlarged view illustrating a state in which the electrode pad is shifted in the +X direction in a conventional film heater.

FIG. 9 is an enlarged view illustrating a state in which the electrode pad is shifted in the −X direction in the conventional film heater.

FIG. 10A is a schematic plan view illustrating a conventional film heater.

FIG. 10B is a cross-sectional view taken along line A-A in FIG. 10A.

### DETAILED DESCRIPTION OF EMBODIMENTS

### (Outline of Embedded Trace Substrate)

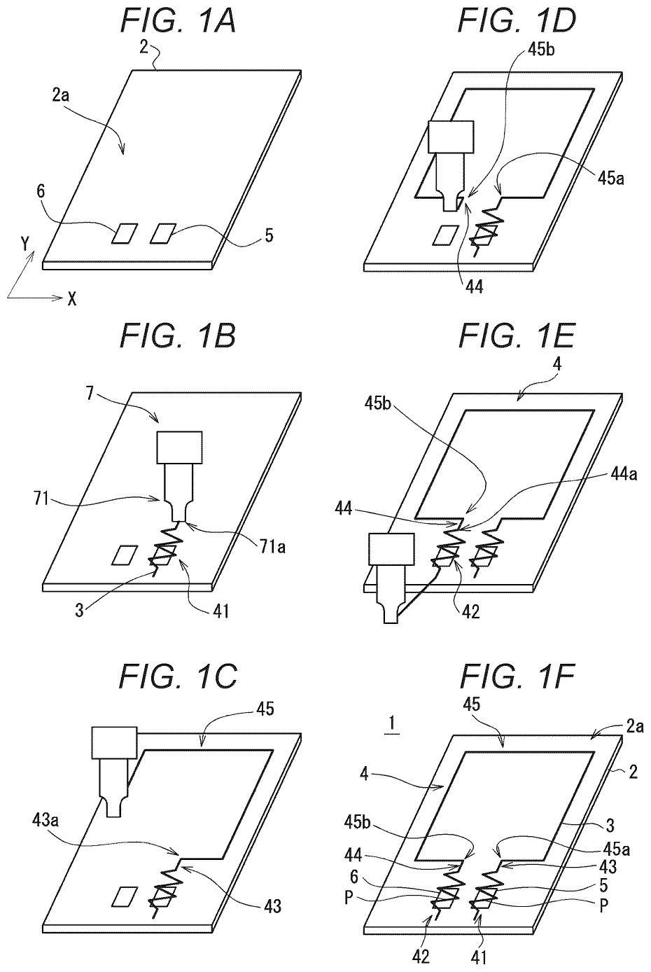

Referring to FIG. 1F, an embedded trace substrate 1 includes a film 2, a circuit 4 including one thin metal wire 3 disposed on a first main surface 2a of the film 2, a first electrode pad 5, and a second electrode pad 6. The circuit 4 includes a functional portion 45, a first wiring portion 43, a second wiring portion 44, a first end portion 41, and a second end portion 42. The functional portion 45 has an arbitrary pattern. The first wiring portion 43 is led out from one end 45a of both ends of the functional portion 45. The second wiring portion 44 is led out from another end 45b of both ends of the functional portion 45. The first end portion 41 extends from the first wiring portion 43 in a direction (−Y direction) away from the functional portion 45 and overlaps the first electrode pad 5. The second end portion 42 extends from the second wiring portion 44 in a direction (−Y direction) away from the functional portion 45 and overlaps the second electrode pad 6.

In the present embodiment, the first end portion 41 and the second end portion 42 have a zigzag shape (an example of a bent shape) in plan view.

The functional portion 45, the first wiring portion 43, and the second wiring portion 44 are embedded in the first main surface 2a of the film 2. The sections of the first end portion 41 and the second end portion 42 overlapping the electrode pads 5 and 6 are not embedded in the first main surface 2a, and the other sections are embedded. In other words, the thin metal wire 3 positioned on the electrode pads 5 and 6 is not embedded in the first main surface 2a, and the thin metal wire 3 not positioned on the electrode pads 5 and 6 is embedded.

In the present embodiment, the functional portion 45 is a heat generating portion, and the embedded trace substrate 1 is a film heater. For example, when a positive voltage is applied to the first electrode pad 5 and a negative voltage is applied to the second electrode pad 6, a current is generated in the circuit 4 constituted by the thin metal wire 3, and the functional portion 45 generates heat. The functional portion 45 has both ends 45a and 45b connected to the first wiring portion 43 and the second wiring portion 44, respectively, and has a loop-like pattern shape. More specifically, the functional portion 45 has a pattern shape extending in the +X direction from the connection portion (i.e., one end 45a) with the first wiring portion 43, and then extending in the +Y direction, the −X direction, the −Y direction, and the +X direction to reach the connection portion (i.e., another end 45b) with the second wiring portion 44. As described above, the functional portion 45 has the connection portions (i.e., both ends 45a and 45b) with the first wiring portion 43 and the second wiring portion 44, and has an arbitrary pattern extending along an XY plane from the connection portions (i.e., both ends 45a and 45b).

The film 2 can have any shape, and has a rectangular shape in the present embodiment. As the film 2, a transparent film, an opaque film, or a colored transparent film can be used. Examples of a material usable for the film 2 include thermoplastic resins such as an ethylene-based resin, a propylene-based resin, a polyolefin-based resin, a thermoplastic polyester-based resin, a polyamide-based resin, polyvinyl chloride, polycarbonate, and an ABS resin. Two or more kinds of the above-mentioned materials may be used. Inorganic fine powder, an organic filler, a dispersant, an antioxidant, a compatibilizer, an ultraviolet stabilizer, an antiblocking agent, an antistatic agent, or the like can be appropriately added to the film 2. The thickness of the film 2 is, for example, 0.05 mm to 1 mm.

Examples of materials usable for the thin metal wire 3 include a material having conductivity such as copper, iron, gold, copper nickel, nickel chromium, or iron nickel chromium. From the viewpoint of electric resistance, durability, and cost, it is preferable to use copper or a copper alloy obtained by combining zinc, lead, tin, silver, aluminum, nickel, beryllium, zirconium, or the like alone with copper or combining a plurality of the above-mentioned materials with copper. The diameter of the thin metal wire 3 is, for example, 0.01 mm to 0.5 mm. The thin metal wire 3 can be made less visible by reducing the diameter as much as possible to, for example, 0.01 mm to 0.2 mm.

Note that the circuit 4 may include a conductive wire including the thin metal wire 3 and an insulating coating layer coating the thin metal wire 3. The insulating coating layer is an insulating resin, and examples of usable resins include polyester, polyethylene, polyurethane, polyvinyl chloride, polyamide, polyimide, polyesterimide, polyamideimide, and fluororesin. The diameter of the conductive wire is, for example, 0.05 mm to 0.3 mm.

Examples of materials usable for the two electrode pads 5 and 6 include a material having conductivity such as copper, phosphor bronze, brass, a Corson alloy, nickel, or molybdenum. A material obtained by plating the above-mentioned material as a base material with nickel, tin, gold, silver, copper, or the like may be used. The size of the electrode pads 5 and 6 is, for example, 5 mm×10 mm. The thickness is, for example, 0.1 mm.

In the present embodiment, the electrode pads 5 and 6 have a quadrangular shape, but the present invention is not limited thereto. The electrode pads 5 and 6 may have, for example, a polygonal shape other than the quadrangular shape, a circular shape, an elliptical shape, an L shape, or the like.

### (Method for Manufacturing Embedded Trace Substrate)

An embodiment of a method for manufacturing the embedded trace substrate 1 described above will be described with reference to FIGS. 1A to 1F.

The method for manufacturing the embedded trace substrate 1 includes a preparation step (not illustrated) of preparing a film 2, an arrangement step (FIG. 1A) of arranging a first electrode pad 5 and a second electrode pad 6 on the peripheral edge of a first main surface 2a of the film 2, a circuit formation step (FIGS. 1B to 1E) of forming a circuit 4 using an ultrasonic welding machine 7, and a connection step (FIG. 1F) of electrically connecting a first end portion 41 and a second end portion 42 of the circuit 4 to the electrode pads 5 and 6.

In the preparation step, the film 2 may be fixed on a stage (not illustrated). In addition, a jig (not illustrated) may be used to facilitate alignment of the film 2. In the arrangement step, the first electrode pad 5 and the second electrode pad 6 are arranged at the peripheral edge of the first main surface 2a of the film 2. In other words, the first electrode pad 5 and the second electrode pad 6 are aligned in the X direction along one side parallel to the X direction (first direction) of the film 2. The two electrode pads 5 and 6 have a quadrangular shape and are arranged along the X direction in parallel to each other with a space therebetween. Each of the two electrode pads 5 and 6 serves as a terminal portion of the embedded trace substrate 1. The two electrode pads 5 and 6 can be fixed on the first main surface 2a using, for example, an adhesive.

Referring to FIG. 1B, the ultrasonic welding machine 7 used in the circuit formation step includes an oscillator (not illustrated) that generates ultrasonic vibration, a horn 71 that propagates the ultrasonic vibration from the oscillator, and the thin metal wire 3. The horn 71 can melt a contact surface of the film 2 with the thin metal wire 3 by applying ultrasonic vibration and embed the thin metal wire 3 in the first main surface 2a of the film 2. The thin metal wire 3 passes through the inside of the horn 71 and is continuously drawn out from a tip 71a of the horn 71 onto the first main surface 2a of the film 2.

In the circuit formation step, first, the thin metal wire 3 is drawn out from the horn 71 by a predetermined length, is embedded in the first main surface 2a of the film 2, and is extended to straddle the first electrode pad 5 in a zigzag shape, by which a first end portion 41 is formed, as illustrated in FIG. 1B. At this time, a bent portion of the zigzag shape is embedded in the first main surface 2a, and the thin metal wire 3 overlapping the first electrode pad 5 is not embedded in the first main surface 2a but is in contact with the upper surface of the first electrode pad 5.

Next, as illustrated in FIG. 1C, the thin metal wire 3 is drawn out in the +Y direction by a predetermined length from an end point of the first end portion 41 that has been embedded and is embedded in the first main surface 2a to form a first wiring portion 43. Next, the thin metal wire 3 is drawn out by a predetermined length from an end point 43a of the first wiring portion 43 that has been embedded and is embedded in the first main surface 2a in an arbitrary pattern extending in the XY plane to form a functional portion 45. The end point 43a of the first wiring portion 43 that has been embedded serves as a start point of the functional portion 45. In other words, the end point 43a of the first wiring portion 43 serves as one end 45a of both ends of the functional portion 45 (see FIG. 1D).

Next, as illustrated in FIG. 1D, the thin metal wire 3 is drawn out from the horn 71 by a predetermined length and is embedded in the first main surface 2a so as to extend in the −Y direction from an end point (i.e., another end 45b) of the functional portion 45, by which a second wiring portion 44 is formed. The end point (i.e., another end 45b) of the functional portion 45 serves as a start point of the second wiring portion 44 and as another end of both ends of the functional portion 45.

Next, as illustrated in FIG. 1E, the thin metal wire 3 is drawn out from an end point 44a of the second wiring portion 44 that has been embedded by a predetermined length, is embedded in the first main surface 2a, and is extended to straddle the second electrode pad 6 in a zigzag shape, by which a second end portion 42 is formed. At this time, a bent portion of the zigzag shape is embedded in the first main surface 2a, and the thin metal wire 3 overlapping the second electrode pad 6 is not embedded in the first main surface 2a but is in contact with the upper surface of the second electrode pad 6. After the second end portion 42 is formed, the thin metal wire 3 is cut at an end point of the second end portion 42 that has been embedded. As a cutting method, for example, a cutter or a nipper can be used.

Finally, in the connection step, the two electrode pads 5 and 6 and the thin metal wire 3 located on (in contact with the upper surfaces of) the two electrode pads 5 and 6 are electrically connected to each other as indicated by a point P in FIG. 1F. A known metal bonding technique such as welding (resistance welding, ultrasonic welding, laser welding, or the like), soldering, brazing, or the like can be used for the connection. The electrode pads 5 and 6 and the thin metal wire 3 may be electrically connected to each other at a plurality of places.

In this way, the embedded trace substrate 1 can be obtained.

### (First Embodiment of Positional-Deviation Absorption Region)

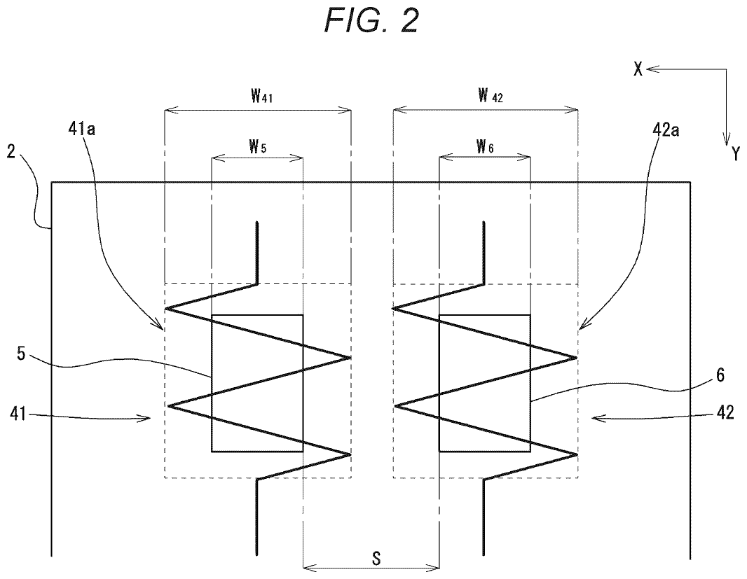

Referring to FIG. 2, the first end portion 41 and the second end portion 42 constitute a first positional-deviation absorption region 41a and a second positional-deviation absorption region 42a, respectively. The first positional-deviation absorption region 41a and the second positional-deviation absorption region 42a are regions indicated by a broken line in the drawing. FIG. 2 illustrates a state in which there is no positional deviation between the first and second electrode pads 5 and 6 and the first and second end portions 41 and 42.

The first positional-deviation absorption region 41a has a width W₄₁, and the second positional-deviation absorption region 42a has a width W₄₂. The widths W₄₁ and W₄₂ are equal to the widths of the zigzag shapes of the end portions 41 and 42, and are set to be larger than widths W₅ and W₆ of the two electrode pads 5 and 6. As a matter of course, when the widths W₄₁ and W₄₂ of the positional-deviation absorption regions 41a and 42a are increased, the allowable magnitude of the positional deviation of the electrode pads 5 and 6 in the X direction is also increased.

For example, when the widths W₅ and W₆ of the electrode pads 5 and 6 are 5 mm, and an interval S between the electrode pads 5 and 6 is 10 mm, each of the widths W₄₁ and W₄₂ can be 15 mm.

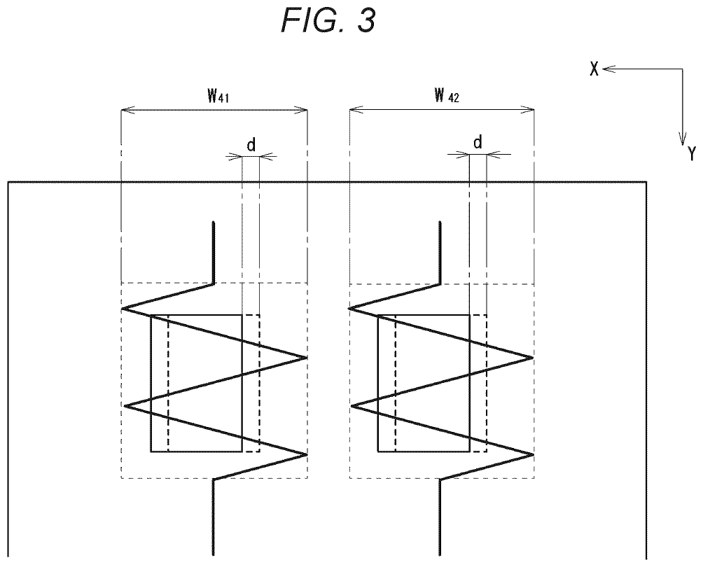

Even when the electrode pads 5 and 6 are shifted, for example, by d in the +X direction as illustrated in FIG. 3, the positional deviation of the electrode pads 5 and 6 can be absorbed because of the positional-deviation absorption regions 41a and 42a having the widths W₄₁ and W₄₂ larger than d. The positional-deviation absorption regions 41a and 42a have the widths W₄₁ and W₄₂, respectively, and thus, even if the positions of the electrode pads 5 and 6 with respect to the film 2 are shifted by d in the X direction, the end portions 41 and 42 overlap the electrode pads 5 and 6. Therefore, it is not necessary to consider the positional deviation of the electrode pads 5 and 6 for the embedded positions of the end portions 41 and 42. That is, the end portions 41 and 42 may be embedded at the same position every time the embedded trace substrate 1 is manufactured.

As described above, the end portions 41 and 42 can be aligned with the electrode pads 5 and 6 without considering the positional deviation of the electrode pads 5 and 6, so that the non-defective rate can be improved.

### (Second Embodiment of Positional-Deviation Absorption Region)

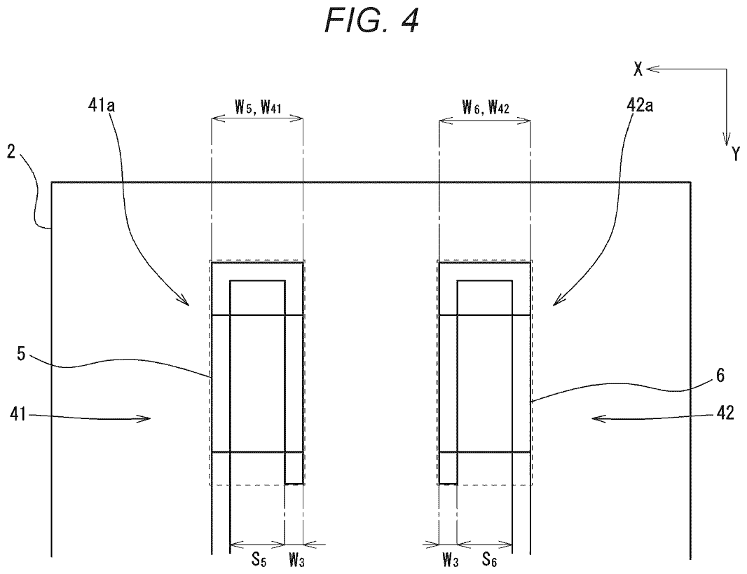

Referring to FIG. 4, the bent shapes of the first end portion 41 and the second end portion 42 may be a U shape in plan view. The first end portion 41 and the second end portion 42 constitute a first positional-deviation absorption region 41a and a second positional-deviation absorption region 42a, respectively. FIG. 4 illustrates a state in which there is no positional deviation between the first and second electrode pads 5 and 6 and the first and second end portions 41 and 42.

The first positional-deviation absorption region 41a has a width W₄₁, and the second positional-deviation absorption region 42a has a width W₄₂. The widths W₄₁ and W₄₂ are equal to the width of the U shape of the end portions 41 and 42, and satisfy the following Expressions (1) and (2), respectively. Here, S₅ and S₆ are intervals between the two thin metal wires 3 straddling the electrode pads 5 and 6 in the Y direction, respectively.

$${W}_{41} = ( 2 \times {W}_{3} ) + {S}_{5} \qquad ( 1 )$$

$${W}_{42} = ( 2 \times {W}_{3} ) + {S}_{6} \qquad ( 2 )$$

When the thin metal wire 3 and the electrode pads 5 and 6 are ultrasonically welded, the widths W₄₁ and W₄₂ of the first positional-deviation absorption region 41a and the second positional-deviation absorption region 42a can be set equal to the widths W₅ and W₆ of the two electrode pads 5 and 6. When the thin metal wire 3 and the electrode pads 5 and 6 are soldered to each other, it is necessary to fix the thin metal wire 3 by placing solders on both sides of the thin metal wire 3 (in other words, placing solders at positions sandwiching the thin metal wire 3), so that W₅ (W₆)>W₄₁ (W₄₂) is established.

With respect to the widths W₅ and W₆ of the electrode pads 5 and 6, the width (diameter) W₃ of the thin metal wire 3 and the intervals S₅ and S₆ are set to values satisfying the following Expressions (3) and (4), respectively.

$${W}_{5} = 2 {W}_{3} + {S}_{5} \qquad ( 3 )$$

$${W}_{6} = 2 {W}_{3} + {S}_{6} \qquad ( 4 )$$

That is, when the widths W₅ and W₆ of the electrode pads 5 and 6 and the width (diameter) W₃ of the thin metal wire 3 are determined, the intervals S₅ and S₆ are obtained from the above Expressions (3) and (4). For example, when the electrode pad 5, 6 having a width W₅ (=width W₆) of 5 mm and the thin metal wire 3 having a width (diameter) W₃ of 0.5 mm are used, the interval S₅ (=S₆) is 4 mm (5−1=4 mm).

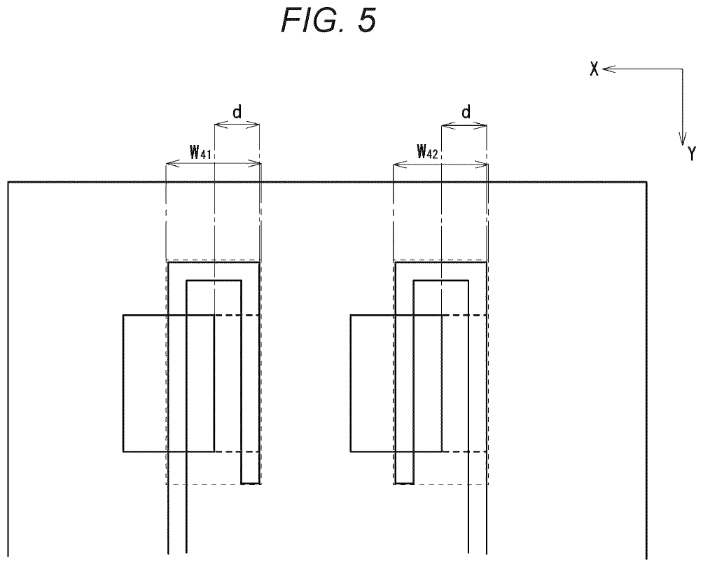

In this way, the first positional-deviation absorption region 41a and the second positional-deviation absorption region 42a are formed in U shapes having the intervals S₅ and S₆, and thus, even when, for example, the electrode pads 5 and 6 are shifted by d (=W₅/2=W₆/2) in the +X direction, sections where the thin metal wire 3 and the electrode pads 5 and 6 overlap (sections where the thin metal wire 3 straddles the electrode pads 5 and 6) are present as illustrated in FIG. 5. That is, the accuracy in alignment between the electrode pads 5 and 6 and the end portions 41 and 42 can be increased, whereby the non-defective rate can be improved.

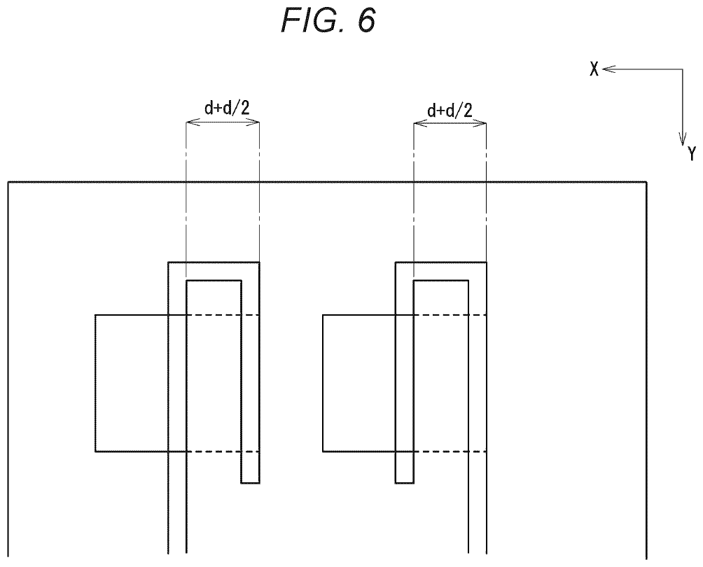

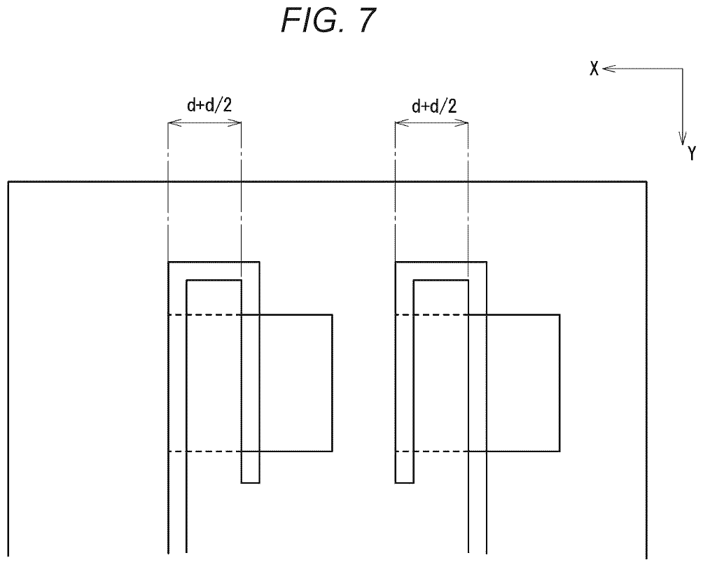

As illustrated in FIGS. 6 and 7, even when the electrode pads 5 and 6 are shifted by d+d/2 in the ±X direction, sections where the thin metal wire 3 and the electrode pads 5 and 6 overlap are present as long as the shapes of the first end portion 41 and the second end portion 42 satisfy the above Expressions (3) and (4). In FIGS. 6 and 7, one thin metal wire 3 overlaps the edge portion of each of the electrode pads 5 and 6. As can be seen from FIGS. 6 and 7, the allowable range of the positional deviation of the electrode pads 5 and 6 in the X direction is d+d/2. Here, since d=W₅/2 (=W₆/2), W₅/2+W₅/4=3W₅/4 (=3W₆/4) is established.

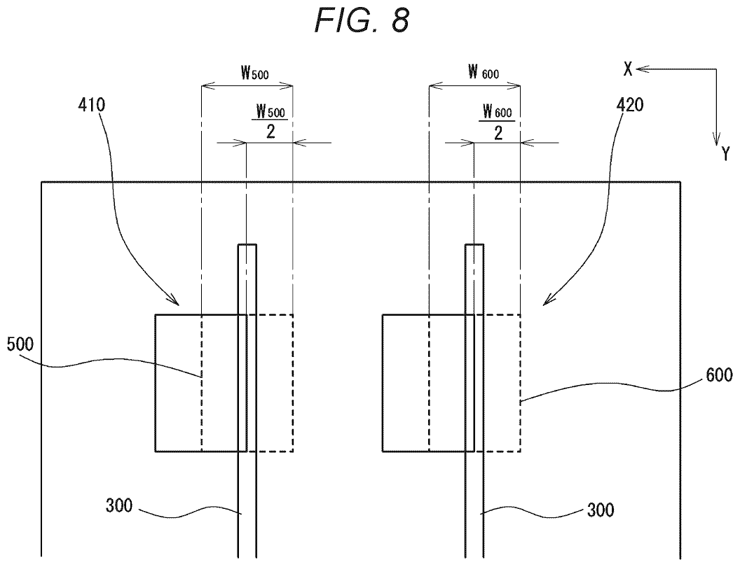

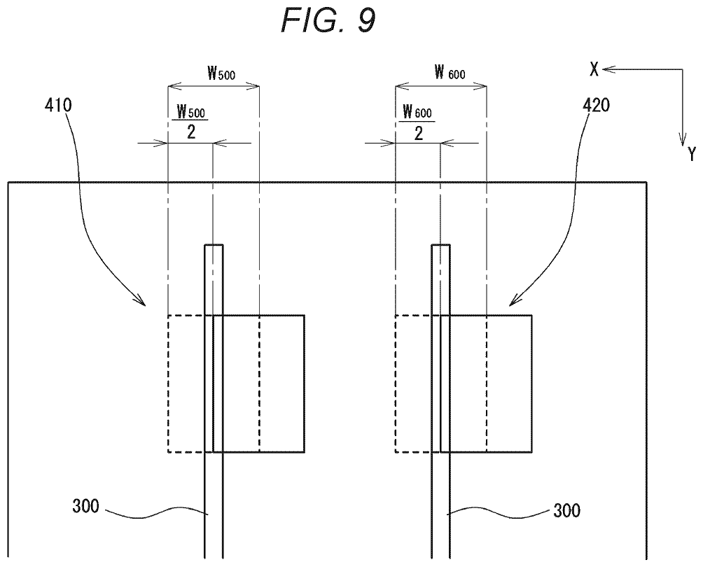

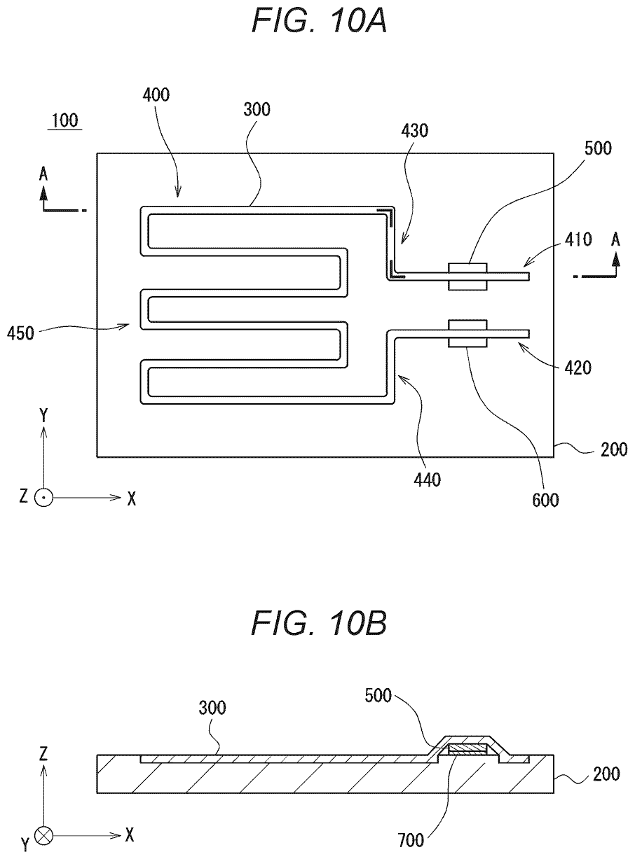

On the other hand, referring to FIGS. 8 and 9, the first end portion 410 and the second end portion 420 of the conventional film heater 100 are straight. In FIGS. 8 and 9, the electrode pads 500 and 600 are shifted in the X direction, but sections where the thin metal wire 300 and the electrode pads 500 and 600 overlap are present. The deviation amount of the electrode pad 500, 600 in FIGS. 8 and 9 is half the width of the electrode pad 500, 600 (W₅₀₀/2, W₆₀₀/2). That is, the allowable range of the positional deviation of the electrode pad 500, 600 in the X direction is half the width of the electrode pad 500, 600 (W₅₀₀/2, W₆₀₀/2).

As described above, by changing the first end portion 41 and the second end portion 42 into a U shape satisfying the above Expressions (3) and (4) from the conventional straight shape, the allowable range of the positional deviation of the electrode pads 5 and 6 in the X direction increases 1.5-fold. That is, the first end portion 41 and the second end portion 42 are easily aligned with the electrode pads 5 and 6, whereby the non-defective rate can be improved.

In the above two embodiments, the embedded position of the thin metal wire 3 is not shifted, and the electrode pads 5 and 6 are shifted. On the contrary, even in a mode in which the electrode pads 5 and 6 are not shifted, and the embedded position of the thin metal wire 3 is shifted, the manufacturing method according to the present disclosure exhibits the same effects as those of the above embodiments. In addition, even in a mode in which both the positions of the electrode pads 5 and 6 and the embedded position of the thin metal wire 3 are shifted, the manufacturing method according to the present disclosure exhibits the same operational effects as those of the above embodiments.

1. A method for manufacturing an embedded trace substrate, the method comprising:
preparing a film;
arranging a first electrode pad and a second electrode pad at a peripheral edge of a first main surface of the film along a first direction so as to be spaced from each other and parallel to each other;
forming a circuit that includes a thin metal wire disposed on the first main surface and that has a functional portion having an arbitrary pattern, a first wiring portion led out from one end of both ends of the functional portion, a second wiring portion led out from another end of both ends of the functional portion, a first end portion constituting a first positional-deviation absorption region, and a second end portion constituting a second positional-deviation absorption region, the first end portion and the second end portion respectively extending from the first wiring portion and the second wiring portion in a direction away from the functional portion and partly overlapping the first electrode pad and the second electrode pad, respectively, the circuit being formed by embedding, in the first main surface of the film, the functional portion, the first wiring portion, the second wiring portion, and sections of the first end portion and the second end portion not overlapping the first electrode pad and the second electrode pad, using an ultrasonic welding machine; and
electrically connecting the first electrode pad and the second electrode pad with the thin metal wire located on the first electrode pad and the second electrode pad, wherein
the ultrasonic welding machine includes a horn that melts a contact surface of the film with the thin metal wire by applying ultrasonic vibration and that embeds the thin metal wire into the first main surface of the film, and the thin metal wire to be continuously drawn out from a tip of the horn onto the first main surface of the film through an inside of the horn, and
the first positional-deviation absorption region and the second positional-deviation absorption region are respectively defined by the first end portion and the second end portion having a bent shape, and have a width for absorbing positional deviation of the first electrode pad and the second electrode pad in the first direction relative to the circuit.

2. The method for manufacturing an embedded trace substrate according to claim 1, wherein
the bent shape is a zigzag shape or a U shape in plan view.
